(19) United States
(12) Patent Application Publication
(10) Pub. No.: US 2013/0119051 A1
(43) Pub. Date: May 16, 2013

(54) DIRECTED HEATING FOR COMPONENT REWORK

(71) Applicant: Apple Inc., San Jose, CA (US)

(72) Inventors: Weyman Chen, Fremont, CA (US); Michael M. Nikkhoo, San Jose, CA (US); Amir Salehi, San Jose, CA (US)

(73) Assignee: Apple Inc., San Jose, CA (US)

(21) Appl. No.: 13/668,154

(22) Filed: Nov. 2, 2012

Related U.S. Application Data
(60) Provisional application No. 61/554,929, filed on Nov. 2, 2011.

(51) Int. Cl. H05K 13/04

(52) U.S. Cl. CPC H05K 13/0486
USPC 219/635

(57) ABSTRACT

Reworking a component solder attached to a printed circuit board is described. The reworking is accomplished by directing energy only at the solder/pad arrangement used to attach the component to the printed circuit board. In one embodiment, the directed energy takes the form of an alternating magnetic field that inductively couples with the solder/pad arrangement. The alternating magnetic field has a frequency at least 800 kHz. In another embodiment, the directed energy takes the form of a laser beam that is concurrently directed at the solder/pad arrangements for liquefying the solder.

### CROSS-REFERENCE TO RELATED APPLICATION

This application claims priority under 35 U.S.C. 119(e) to U.S. Provisional Patent Application No. 61/554,929, filed Nov. 2, 2011, and entitled “DIRECTED HEATING FOR COMPONENT REWORK” by Chen et al. which is incorporated herein by reference in its entirety and for all purposes.

### BACKGROUND

1. Technical Field

The present invention relates generally to assembly of electronic products. More particularly, a method and an apparatus are described for reworking components already having been soldered to a printed circuit board, or PCB. Specific embodiments described using non-destructive techniques to de-couple the component to be reworked and the PCB.

2. Related Art

During the assembly of many electronic products, various components must be attached to a printed circuit board. Generally, the components are attached at contact pads that act as both a support structure and an electrical connection to electrical traces incorporated into the printed circuit board. Generally, the component includes a number of connection tabs, or pins, that can, for example, be solder connected to the electrical connection, also referred to as a pad. Generally, the pads are formed of thin conductive material such as aluminum or copper that forms a good bond with the solder that is generally applied during what is referred to as a solder reflow operation.

Once the component is successfully attached and electrically connected to the appropriate contact pads, either the component or the assembled product (or single PCB, if needed) is functionally tested. If the functional testing proceeds successfully, the component, PCB, or electronic product can advance to the next step in the manufacturing process. However, if the functional testing fails, then it may be necessary to remove the faulty component (if that is in fact what is causing the failure) or at least provide access to the faulty component. Unfortunately, in order to release, or rework, the faulty component, the soldered connections must be released without damaging the underlying PCB or contact or the component itself. Therefore, only a limited number of rework cycles can be realized without causing an undue likelihood of causing damage.

Thus there exists a need for a method and an apparatus for providing a rework process having little or no damaging impact on the reworked assembly.

### SUMMARY

The embodiments relate to a system, method, and computer readable medium for efficiently removing soldered electrical components from a printed circuit board.

In a first embodiment a component rework station for efficiently removing an electrical component from a printed circuit board (PCB) is disclosed. The component rework station includes at least the following: (1) an alternating current power supply; (2) a non-magnetic housing comprising an aperture disposed along a bottom surface of the non-magnetic housing; (3) a magnetic energy emitter embedded within an upper portion of the non-magnetic housing and electrically coupled to the alternating current power supply; and (4) a magnetic concentrator embedded within a lower portion of the non-magnetic housing and above the aperture. The magnetic concentrator is configured to do the following: receive a first magnetic field from the magnetic energy emitter at a first magnetic flux density; provide a second magnetic field at a second flux density greater than the first flux density; and direct the second magnetic field towards a soldered connection electrically and mechanically coupling the electrical component to the PCB. The directed second magnetic field transfers energy to the soldered connection by generating eddy currents within the soldered connection causing it to liquefy, thereby allowing removal of the electrical component.

In another embodiment a method for removing a number of electrical components from a printed circuit board (PCB). The method includes at least the following steps: (1) emitting a magnetic field at a first flux density; (2) receiving a portion of the emitted magnetic field at each of a number of magnetic concentrators; (3) providing an altered magnetic field from each of the plurality of magnetic concentrators, the altered magnetic fields having a second flux density greater than the first flux density; (4) directing and shaping each of the altered magnetic fields towards one of a plurality of soldered connections. Each soldered connection electrically couples one of the plurality of electrical components to the PCB, and the shaped and directed altered magnetic fields are inductively coupled to an associated one of the soldered connections. The method further includes simultaneously liquefying the plurality of soldered connections by the inductively coupled altered magnetic fields; and removing the plurality of electrical components while the plurality of soldered connections are still liquefied.

In yet another embodiment a non-transitory computer readable medium for storing computer code executable by a processor associated with a computer controlled component rework station is disclosed. The non-transitory computer readable medium includes at least the following: (1) computer code for emitting a first magnetic field at a first flux density; (2) computer code for receiving a portion of the emitted first magnetic field at a magnetic concentrator; (3) computer code for providing a second magnetic field from the magnetic concentrator, the second magnetic fields having a second flux density greater than the first flux density; (4) computer code for directing and shaping the second magnetic fields towards a soldered connection that electrically couples an electrical component to a PCB, and the shaped and directed second magnetic field is inductively coupled to the soldered connection; (5) computer code for simultaneously liquefying the plurality of soldered connections by the inductively coupled altered magnetic fields; and (6) computer code for removing the electrical component while the soldered connection is still liquefied.

### BRIEF DESCRIPTION OF THE DRAWINGS

The described embodiments will be readily understood by the following detailed description in conjunction with the accompanying drawings, wherein like reference numerals designate like structural elements, and in which:

FIG. 1 shows a flowchart detailing a process in accordance with the invention;

FIG. 2 shows a rework station in accordance with the described embodiments; and

FIG. 3 shows a block diagram for a representative apparatus that can be used in automation of component rework station operations.

### DETAILED DESCRIPTION OF EXAMPLE EMBODIMENTS

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessarily obscuring the present invention.

The present invention relates generally to using directed energy to remove components from a printed circuit board (PCB). In one embodiment, the components are attached to contact pads on the PCB using an attachment medium such as solder. The solder can receive the directed energy at least a portion of which is absorbed in sufficient quantity to liquefy at least a portion of the solder. In one implementation the directed energy can take the form of an alternating magnetic field provided by an electromagnet powered by alternating current. A magnetic focusing device also referred to as a lens or concentrator can be used to increase a flux density in the vicinity of the solder to be reworked. In some embodiments each magnetic focusing device can be arranged directly above each solder connection point that requires removal, while in other embodiments an offset distance can be established between the concentrator and each of the soldered connections. In this way, the coupling between the contact pad, the solder, and the magnetic field can cause eddy currents to form having the effect of transferring at least some of the energy from the magnetic field to the contact pad and solder resulting in the solder reaching a high enough temperature that the solder liquefies. When the solder liquefies, the component can be conveniently removed from being in contact with the pad without unduly damaging the underlying PCB or contact pad.

In one embodiment, the frequency of the alternating magnetic field can be high enough that a “skin effect” can prevent the magnetic field from penetrating more than about 0.1 mm into the contact pad. Generally speaking, as the frequency of an alternating magnetic field increases the resulting field size is reduced, thereby concentrating the magnetic field in a smaller volumetric area. In this way, the alternating magnetic field can be shaped so that most of the energy deposited in the contact pad remains on the surface of the contact pan and can be directed in the vicinity of the solder. Accordingly, the frequency of the alternating magnetic field can be on the order of about 900 kHz or more. In one embodiment an alternating magnetic field can be generated by running alternating current through a metallic loop or wire, the alternating frequency of the current corresponding generally to the resulting alternating frequency of the magnetic field. In this way, the alternating magnetic field can be considered to alternate at a radio frequency, or RF.

In the described embodiment, the duration of the alternating (or RF) magnetic field can be on the order of a few milliseconds to a few seconds. In this way, the amount of time that the energy is deposited by the alternating magnetic field can be substantially less than the amount of time required for heat to be transported through the contact pad to the PCB substrate. Accordingly, the high frequency and the short duration of the alternating magnetic field essentially limit the energy deposition to that portion of the contact pad in close proximity to the solder. In this way, the solder is quickly liquefied allowing easy removal of the component without causing harmful heating in other portions of the PCB substrate. It should be noted that when a plurality of contacts pads are used to attach the component to the PCB, each of the plurality of contact pads are exposed to the directed energy at about the same time. In this way, the at least partially liquefied solder on one contact pad does not substantially cool and re-harden when the solder on another contact pad is liquefied as would be the case when the contacts receive the directed energy sequentially.

In another embodiment, the directed energy can take the form of light energy in the form of a laser beam. The laser beam can be derived from any number of lasing materials such as argon (Ar), CO₂, and so on. In order to assure that substantially all of the contacts are subjected to the directed energy in the form of the laser beam at about the same time, the laser beam, or laser beams, can be split in to a number of different laser beams directed at particular contact pads at the same time.

Therefore, the following discussion describes a method and apparatus for reworking component solder attached to a printed circuit board. In the described embodiments, the rework can be accomplished by using any suitable form of directed energy. In one embodiment, the directed energy can take the form of a magnetic field that inductively couples with a pad/solder arrangement. In such an embodiment, the magnetic field can be an alternating magnetic field having a frequency of at least 900 kHz. In another embodiment, the directed energy can take the form of a laser beam arranged to provide the directed energy concurrently at substantially all of the contact/solder arrangements at the same time.

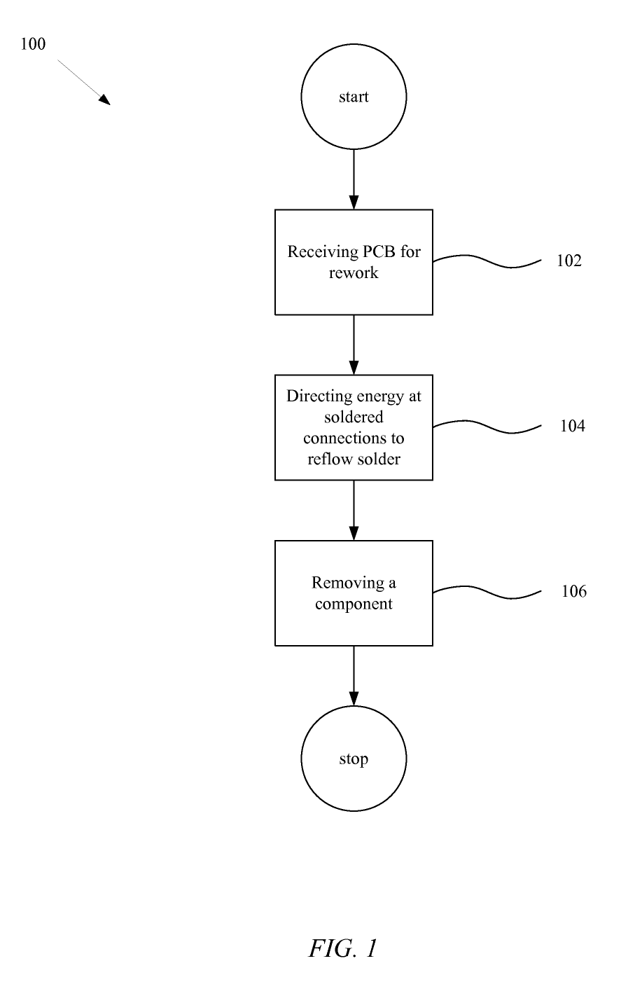

FIG. 1 shows a flowchart describing process 100 in accordance with the described embodiments. Process 100 can be performed by receiving at 102 a printed circuit board for rework, the printed circuit board (PCB) having at least one component coupled to the PCB by a soldered connection. By rework it is meant that the at least one component must be physically detached from the printed circuit board without damaging the contact or underlying substrate. At 104, energy is directed at the solder/contact arrangement in sufficient quantity causing the solder to reflow, or liquefy, thereby reducing the ability of the solder to retain the component on the PCB. In one embodiment, the directed energy takes the form of an alternating magnetic field having a frequency high enough that the skin effect at the solder/contact precludes the alternating magnetic field from penetrating more than about 0.1 mm into the contact pad. In another embodiment, the directed energy takes the form of a laser beam. The laser beam directs sufficient energy to the solder/pad arrangement to liquefy at least a portion of the solder. The laser beam can be processed through a beam splitter or the like arranged to split the beam in such a way that substantially all contacts/pads are lased at about the same time. At 106, subsequent to the directed energy at least partially liquefying the solder, the component is physically removed from the PCB allowing components that require rework to be attended to.

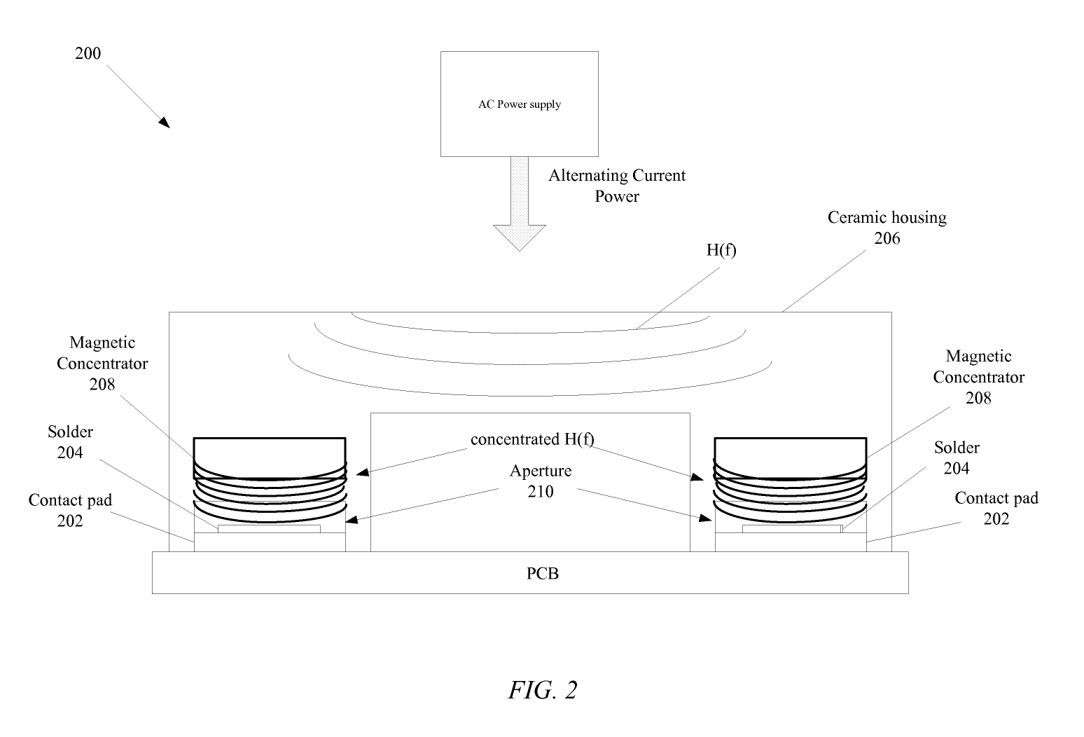

FIG. 2 shows a cross sectional view of a representative rework station 200 in accordance with the described embodiments. Rework station 200 can use an alternating magnetic field H(f) having a frequency f sufficient to preclude the alternating magnetic field H(f) from penetrating more than about 0.1 mm into contact pad 202 on which is located solder 204. In the described embodiment, frequency f is at least about 800-900 kHz. Alternating magnetic field H(f) can be provided by way of magnetic loops (not shown) embedded in housing 206. In some embodiments high amounts of energy can be transmitted through the magnetic loops and consequently can require cooling. That cooling can be accomplished by a magnetic coil cooling system. In one embodiment the magnetic coil cooling system can be embodied by pumping cooling fluid through a center portion of metallic wire forming the magnetic loops. After the cooling fluid passes through the magnetic loops, heat can be removed by a heat exchanger. Housing 206 can be formed of heat resistant and non-magnetic material such as a ceramic material. Since the housing is non-magnetic it doesn't interfere with transmission of the alternating magnetic field emanating from the magnetic loops. The alternating magnetic field H(f) can be concentrated by magnetic lenses or concentrators 208 formed of appropriate material. For example, magnetic lens 208 can be formed of ferromagnetic material capable of focusing magnetic field lines in such a way that the magnetic flux through aperture 210 is substantially increased in relation to what it would otherwise be without magnetic lens 208.

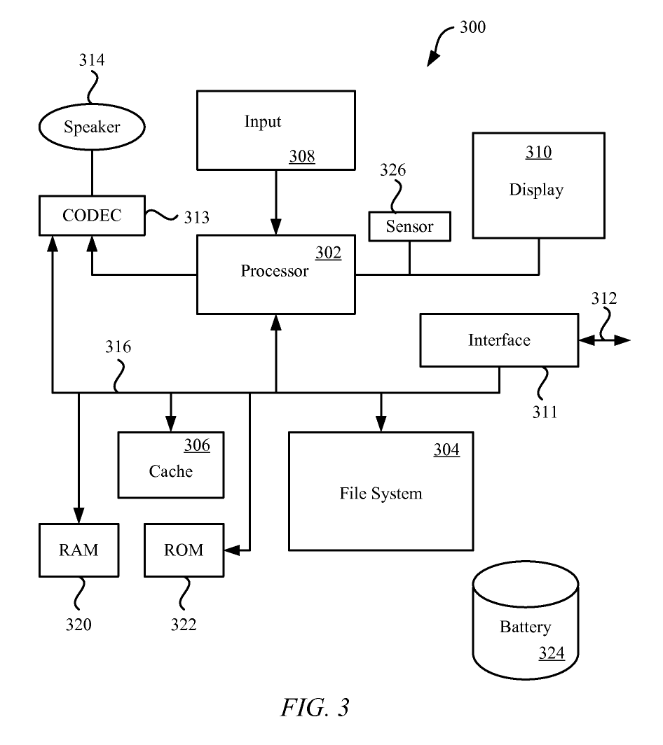

FIG. 3 is a block diagram of an electronic device suitable for controlling some of the processes in the described embodiment. Electronic device 300 can illustrate circuitry of a representative computing device. Electronic device 300 can include a processor 302 that pertains to a microprocessor or controller for controlling the overall operation of electronic device 300. Electronic device 300 can include instruction data pertaining to manufacturing instructions in a file system 304 and a cache 306. File system 304 can be a storage disk or a plurality of disks. In some embodiments, file system 304 can be flash memory, semiconductor (solid state) memory or the like. The file system 304 can typically provide high capacity storage capability for the electronic device 300. However, since the access time to the file system 304 can be relatively slow (especially if file system 304 includes a mechanical disk drive), the electronic device 300 can also include cache 306. The cache 306 can include, for example, Random-Access Memory (RAM) provided by semiconductor memory. The relative access time to the cache 306 can substantially shorter than for the file system 304. However, cache 306 may not have the large storage capacity of file system 304. Further, file system 304, when active, can consume more power than cache 306. Power consumption often can be a concern when the electronic device 300 is a portable device that is powered by battery 324. The electronic device 300 can also include a RAM 320 and a Read-Only Memory (ROM) 322. The ROM 322 can store programs, utilities or processes to be executed in a non-volatile manner. The RAM 320 can provide volatile data storage, such as cache 306

Electronic device 300 can also include user input device 308 that allows a user of the electronic device 300 to interact with the electronic device 300. For example, user input device 308 can take a variety of forms, such as a button, keypad, dial, touch screen, audio input interface, visual/image capture input interface, input in the form of sensor data, etc. Still further, electronic device 300 can include a display 310 (screen display) that can be controlled by processor 302 to display information to the user. Data bus 316 can facilitate data transfer between at least file system 304, cache 306, processor 302, and controller 313. Controller 313 can be used to interface with and control different manufacturing equipment through equipment control bus 314. For example, control bus 314 can be used to control a computer numerical control (CNC) mill, a press, a component rework station or other such equipment. For example, processor 302, upon a certain manufacturing event occurring, can supply instructions to control manufacturing equipment through controller 313 and control bus 314. Such instructions can be stored in file system 304, RAM 320, ROM 322 or cache 306.

Electronic device 300 can also include a network/bus interface 311 that couples to data link 312. Data link 312 can allow electronic device 300 to couple to a host computer or to accessory devices. The data link 312 can be provided over a wired connection or a wireless connection. In the case of a wireless connection, network/bus interface 311 can include a wireless transceiver. Sensor 326 can take the form of circuitry for detecting any number of stimuli. For example, sensor 326 can include any number of sensors for monitoring a manufacturing operation such as for example a Hall Effect sensor responsive to external magnetic field, an audio sensor, a light sensor such as a photometer, computer vision sensor to detect clarity, a temperature sensor to monitor a molding process and so on.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line used to fabricate computer components such as computer housing formed of metal or plastic. The computer readable medium is any data storage device that can store data which can thereafter be read by a computer system. Examples of the computer readable medium include read-only memory, random-access memory, CD-ROMs, DVDs, magnetic tape, optical data storage devices, and carrier waves. The computer readable medium can also be distributed over network-coupled computer systems so that the computer readable code is stored and executed in a distributed fashion.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. It will be apparent to one of ordinary skill in the art that many modifications and variations are possible in view of the above teachings.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

What is claimed is:

1. A component rework station for efficiently removing an electrical component from a printed circuit board (PCB), comprising:
an alternating current power supply;
a non-magnetic housing comprising an aperture disposed along a bottom surface of the non-magnetic housing;
a magnetic energy emitter embedded within an upper portion of the non-magnetic housing and electrically coupled to the alternating current power supply; and
a magnetic concentrator embedded within a lower portion of the non-magnetic housing and above the aperture, the magnetic concentrator configured to receive a first magnetic field from the magnetic energy emitter at a first magnetic flux density, provide a second magnetic field at a second flux density greater than the first flux density, and direct the second magnetic field towards a soldered connection electrically and mechanically coupling the electrical component to the PCB,
wherein the directed second magnetic field transfers energy to the soldered connection by generating eddy currents within the soldered connection causing it to liquefy, thereby allowing removal of the electrical component.

2. The component rework station as recited in claim 1, wherein the aperture disposed along the bottom surface of the non-magnetic housing comprises a plurality of apertures disposed across a bottom surface of the non-magnetic housing, and wherein the magnetic concentrator comprises a plurality of magnetic concentrators.

3. The component rework station as recited in claim 2, wherein the plurality of apertures and magnetic concentrators are configured to simultaneous increase magnetic flux at a plurality of soldered connections, thereby efficiently liquefying the soldered connections and allowing easy removal of the electrical component.

4. The component rework station as recited in claim 1, wherein the plurality of apertures is configured to at least partially surround a plurality of contact pads coupled to the PCB.

5. The component rework station as recited in claim 4, wherein the alternating current power supply provides power to the magnetic energy emitter.

6. The component rework station as recited in claim 5, wherein the alternating current power supply operates at a frequency between about 800 kHz and 900 kHz, thereby causing the alternating magnetic field to operate at a frequency of between about 800 kHz and 900 kHz.

7. The component rework station as recited in claim 6, wherein the plurality of magnetic concentrators focus energy from the alternating magnetic field onto solder connections attaching the electrical component to the contact pads.

8. The component rework station as recited in claim 4, wherein the generated alternating magnetic field does not penetrating more than about 0.1 mm into any of the plurality of contact pads upon which each of the plurality of soldered connection is disposed.

9. The component rework station as recited in claim 7, further comprising:
a magnetic energy emitter cooling system comprising:
a cooling fluid pump,
a heat exchanger, and
a cooling fluid conduit,
wherein the magnetic energy emitter is a series of wound wire spirals configured to direct energy at the soldered connections, and wherein the cooling fluid conduit runs through a central portion of the wound wire, thereby regulating temperature of the wire while alternating current flows through the wire.

10. The component rework station as recited in claim 9, wherein the non-magnetic housing is a ceramic housing.

11. A method for removing a plurality of electrical components from a printed circuit board (PCB), the method comprising:
emitting a magnetic field at a first flux density;
receiving a portion of the emitted magnetic field at each of a plurality of magnetic concentrators;
providing an altered magnetic field from each of the plurality of magnetic concentrators, the altered magnetic fields having a second flux density greater than the first flux density;
directing and shaping each of the altered magnetic fields towards one of a plurality of soldered connections, wherein each soldered connection electrically couples one of the plurality of electrical components to the PCB, and wherein the shaped and directed altered magnetic fields are inductively coupled to an associated one of the soldered connections;
simultaneously liquefying the plurality of soldered connections by the inductively coupled altered magnetic fields; and
removing the plurality of electrical components while the plurality of soldered connections are still liquefied.

12. The method as recited in claim 11, wherein the emitted magnetic field has a frequency in the range of about 900 kHz, the frequency established by an alternating current power supply electrically coupled to a magnetic field emitter.

13. The method as recited in claim 12, wherein the altered magnetic fields do not extend more than 0.1 mm past the plurality of soldered connections.

14. The method as recited in claim 13, wherein the alternating magnetic field emitter and the magnetic concentrators are both held in place with respect to one another by a non-magnetic housing inside of which both are embedded.

15. The method as recited in claim 14, wherein the altered magnetic fields propagate through apertures disposed in a bottom surface of the non-magnetic housing, prior to being inductively coupled to each of the soldered connections.

16. The method as recited in claim 11, wherein eddy currents established within each of the soldered connections by the inductive coupling with the altered magnetic fields provides the energy required to liquefy the soldered connections.

17. A non-transitory computer readable medium for storing computer code executable by a processor associated with a computer controlled component rework station, the non-transitory computer readable medium comprising:
computer code for emitting a first magnetic field at a first flux density;
computer code for receiving a portion of the emitted first magnetic field at a magnetic concentrator;
computer code for providing a second magnetic field from the magnetic concentrator, the second magnetic fields having a second flux density greater than the first flux density;
computer code for directing and shaping the second magnetic fields towards a soldered connection, wherein the soldered connection electrically couples an electrical component to a PCB, and wherein the shaped and directed second magnetic field is inductively coupled to the soldered connection;
computer code for simultaneously liquefying the plurality of soldered connections by the inductively coupled altered magnetic fields; and
computer code for removing the electrical component while the soldered connection is still liquefied.

18. The non-transitory computer readable medium as recited in claim 17, further comprising:
computer code for powering a magnetic field emitter that emits the first flux density with an alternating current power supply,
wherein the emitted first magnetic field is an alternating magnetic field.

19. The non-transitory computer readable medium as recited in claim 18, wherein the alternating current power supply alternates at a high frequency between about 800 kHz and 900 kHz.

20. The non-transitory computer readable medium as recited in claim 19, wherein the first magnetic field is emitted for between about a few milliseconds and a few seconds.
